(19) United States
(12) Patent Application Publication
(10) Pub. No.: US 2013/0242494 A1
(43) Pub. Date: Sep. 19, 2013

(54) Drive Unit With Interface

(71) Applicant: CONTROL TECHNIQUES LTD, Newtown (GB)

(72) Inventor: Jonathan Robert Holman, Shrewsbury (GB)

(73) Assignee: CONTROL TECHNIQUES LTD, Newtown (GB)

(21) Appl. No.: 13/778,496

(22) Filed: Feb. 27, 2013

(30) Foreign Application Priority Data
Feb. 29, 2012 (GB) 1203592.9

(51) Int. Cl. H05K 7/18

(52) U.S. Cl. CPC H05K 7/183
USPC 361/679.21

(57) ABSTRACT

A drive unit for housing components of a drive system for an electrical machine, such as an electric motor, comprises a cabinet having opposed first and second relatively narrow faces and a wide face between them. An interface for inputting and deriving data is mounted on a bracket to the unit and faces in the same direction as the wide face. The unit can be installed conveniently in situations in which depth is limited, while at the same time enabling the drive unit to be programmed and set in a convenient way.

### CROSS-REFERENCE TO RELATED APPLICATION

This application claims the benefit and priority of Great Britain Patent Application No. GB 1203592.9 filed Feb. 29, 2012. The entire disclosure of the above application is incorporated herein by reference.

### FIELD

This invention relates to drive units for electrical equipment.

### BACKGROUND

In many applications of electrical equipment, such as electric motors, the operation is governed by a processor-based drive unit that controls the supply of electrical power to the equipment. In some applications the drive unit has an interface for programming and diagnostic purposes. The drive unit itself is usually housed in a modular enclosure. Conventionally, to conserve space the enclosures are relatively thin but relatively deep such that they can house the circuits of electronic components, etc. on circuit boards that extend along the depth of the enclosure. The drive units can be arranged side by side with the relatively thin aspect showing to the front. Sockets and other connectivity and set-up features are located on the front, top and bottom of the enclosure as often the only convenient location which is exposed for the access. Sometimes in racks such drive units may be stacked in a row such that the front, top and bottom are the only accessible faces.

The common feature of the typical drive unit enclosure is its reliance on being thin but deep and using the thin front or rear face for access. This is not necessarily advantageous in all applications. In particular, the back of such a drive unit enclosure is usually arranged up against a wall. However, the need for connecting cables for power, data, etc. requires a clearance so that the enclosure itself cannot be arranged right up against a bulkhead. Furthermore, cooling fans are usually installed to blow air in and out of the enclosure from the back which also requires clearance. It is, of course, possible to remove all such connections and other features of a drive unit to the thin front face but this still means that the enclosure is both relatively thin and relatively deep. It has been recognised that the conventional enclosure for a drive unit of this kind is actually wasteful of space in many applications. They are very often of standard dimensions and this waste of space means there are situations in which they are unusable or awkward to install and/or access due to their dimensions and configuration.

### SUMMARY

According to disclosed embodiments, a drive unit has in components of a drive for an electrical machine comprises an enclosure having opposing narrow faces and a wide face extending between the narrow faces. The unit further comprising an interface mounted on the unit and arranged to face in generally the same direction as the wide face of the enclosure. The unit can be installed in relatively shallow spaces while enabling it to be accessed for programming and data transmission because the interface faces out from the wide face which is normally left plain or at least devoid of any features which enable a user to interface with the unit itself.

Preferably, the interface is mounted on the unit by a bracket. The bracket may enable orientation of the interface or it may be fixed.

Preferably, the interface comprises a screen facing generally in the same direction as the wide face of the unit. The interface may additionally or alternatively comprise a set of push buttons for programming the unit.

### DRAWINGS

Embodiments will be described by way of example with reference to the accompanying drawings in which:

FIG. 1 is a view of a drive unit; and

FIGS. 2-4 are views of parts of the unit of FIG. 1.

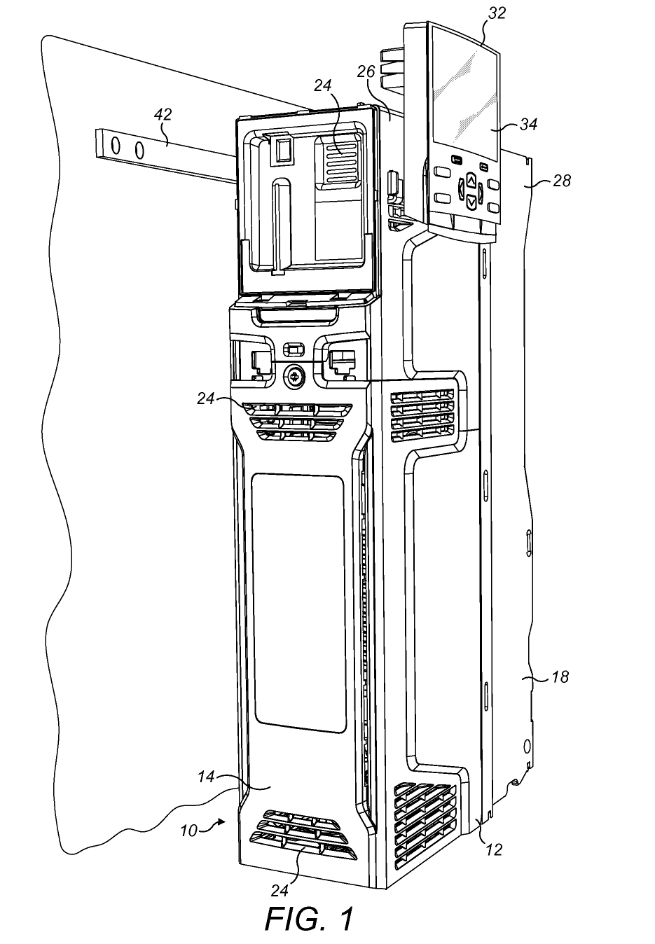

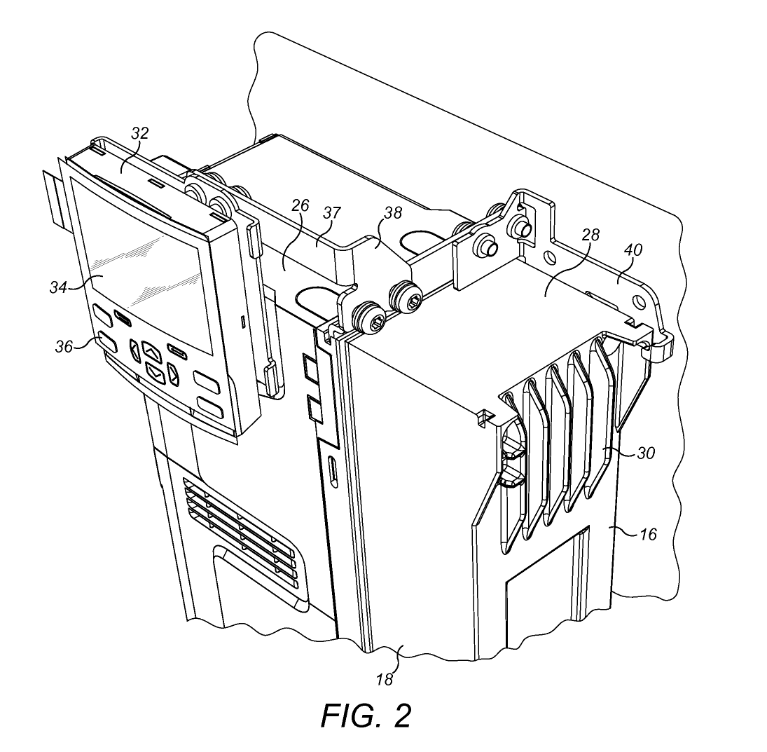

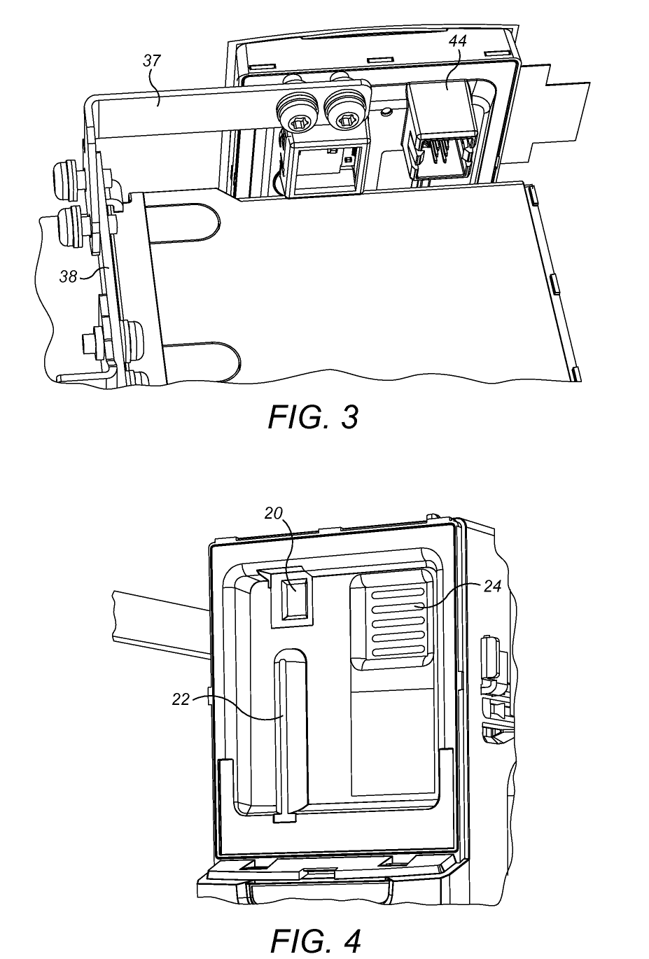

### DETAILED DESCRIPTION

Referring to the drawings, a drive unit 10 for an electric motor (not shown) comprises the control and power electronics for controlling the electric motor driving, for example, a lift (elevator). In a lift shaft there is relatively little space. Lifts are often confined in the space available for them, especially when they are retrofitted into a building.

The drive unit 10 comprises a rigid enclosure 12 made up of a first narrow face 14 and a second narrow face 16 between which extends an outer wide face 18. The first narrow face 14 has various features including, in this example, a socket 20, a CD-ROM aperture 22 and various grills 24 for cooling fans located within the cabinet.

In this embodiment the unit comprises a control module 26 and a power electronics module 28. The two modules are connected together so that the wide face is made up of the surfaces of the two. The control module part of the enclosure is made of rigid plastics material, whereas the power electronics module is a metal (for example aluminium) enclosure able to withstand the heat that is potentially generated by the power electronics it houses. The second narrow face of the enclosure as a whole is thus the narrow face of the power module and comprises a series of heat sink fins 30.

An interface 32 is mounted on the unit in front of and at the top of the control module 26. The interface 32 comprises a screen 34 and a set of push buttons 36 for inputting settings and data. The interface 32 can be any user engageable device whereby information can be input and/or derived. In this embodiment the interface is fixed to a bracket 37 extending from a flange 38 on the power module and faces outwardly in the same direction as the wide face of the enclosure for the unit. The interface 32 could be sited at various locations facing in the same general direction as the wide face 18 of the enclosure. For example, it could be arranged in front of the wide face to one side or below it.

The unit 10 is mounted on a wall or bulkhead by a wall-mounted bracket 40 attached to the flange of the power module 28. The majority of the weight in the unit is in the power module. Thus, the power module is directly suspended from the wall-mounted brackets towards the top of the unit. In this embodiment the lighter control module 26 is suspended from the power module but is further supported by the wall or bulkhead by its own mounting bracket 42. Similar support for both the power and control modules can be repeated nearer the lower part of the unit as well as towards the top.

The interface 32 is connected to the control module 26 by a flexible power and data wiring loom (not shown) running between the socket 20 on the narrow face of the control module and a corresponding connection point 44 on the back of the interface.

While the bracket 36 fixedly mounts the interface to the unit, it is equally possible to use a bracket that allows the position and orientation of the interface to be adjusted.

The drive unit disclosed is particularly useful in confined spaces where there is insufficient space both to install a typical drive unit without eliminating access to the part of the unit where an interface would normally be arranged. As mentioned, an example of such an application is a lift shaft. Other applications of the disclosed drive unit exist where similar space constraints apply.

1. A drive unit for housing the components of a drive system for an electrical machine comprising an enclosure having opposing first and second narrow faces and a wide face extended between the narrow faces, the unit further comprising an interface mounted and arranged to face in generally the same direction as the wide face of the unit.

2. A unit as claimed in claim 1 in which the interface is fixedly mounted on the unit by a bracket.

3. A unit as claimed in claim 1 in which the interface is adjustably mounted on the unit by a bracket.

4. A unit as claimed in claim 1 in which the enclosure comprises a control module and a power module, the wide face of the cabinet comprising corresponding surfaces of the control module and the power module.

5. A unit as claimed in claim 1 further comprising bracket secured behind the wide face for suspending the unit from a wall or bulkhead.

6. A unit as claimed in claim 4 further comprising a bracket secured behind the wide face for suspending the unit from a wall or bulkhead in which the bracket is fixed to the power module.

7. A unit as claimed in claim 1 in which the interface comprises a screen facing generally in the same direction as the wide face of the unit.

8. A unit as claimed in claim 1 in which the interface comprises input buttons facing generally in the same direction as the wide face of the unit.

9. A unit as claimed in claim 1 in which the interface is connected with the cabinet by a flexible wiring loom.

10. A unit as claimed in claim 1 in which the interface is mounted in front of the wide face and protrudes above it.
